(19) United States
(12) Patent Application Publication
(10) Pub. No.: US 2025/0047769 A1
(43) Pub. Date: Feb. 6, 2025

(54) ENCLOSURE WITH BRACKET CONFIGURED TO ROTATE SO AS TO ALLOW MOUNTING OF DIFFERENT SIZED TELECOMMUNICATION COMPONENTS IN THE ENCLOSURE

(71) Applicant: PPC BROADBAND, INC., East Syracuse, NY (US)

(72) Inventor: Gilibaldo RUIZ, East Syracuse, NY (US)

(73) Assignee: PPC BROADBAND, INC., East Syracuse, NY (US)

(21) Appl. No.: 18/793,371

(22) Filed: Aug. 2, 2024

Related U.S. Application Data
(60) Provisional application No. 63/530,813, filed on Aug. 4, 2023.

(51) Int. Cl. H04M 1/02; H05K 7/16

(52) U.S. Cl. CPC H04M 1/0293; H05K 7/16

(57) ABSTRACT

A telecommunication component mounting system configured to allow mounting of different sized components, including: a first mounting portion configured to attach a telecommunication component to an enclosure; and a second mounting portion configured to attach the telecommunication component to the enclosure. The first mounting portion comprises a moving portion that is configured to engage the enclosure; the moving portion comprises a retaining portion that is configured to engage an engaging portion of the enclosure such that the retaining portion slidingly moves relative to the engaging portion; the retaining portion is a curved slot; and the moving portion is configured to rotate about an axis such that different sized telecommunication components are permitted to be mounted in the enclosure so as to avoid a need for different mounting parts for different sized telecommunication components, thereby resulting in a reduction of parts needed to mount different sized telecommunication components to the enclosure.

### CROSS-REFERENCE TO RELATED APPLICATION

This application claims the benefit of U.S. Provisional Application No. 63/530,813 filed Aug. 4, 2023, which is currently pending, the disclosure of which is hereby incorporated by reference herein in its entirety.

### BACKGROUND

The present disclosure relates generally to telecommunications enclosures and, in particular, to a telecommunications enclosure having a device mounting bracket that adapts to telecommunication components of different sizes.

Devices such as, for example, ethernet routers are often housed in an enclosure on a telephone or other service pole to protect the device from the weather and other elements. In some situations, it may be desirable to provide one enclosure and device mounting hardware for housing a device such as, for example, an ethernet router that can be one of various different sizes.

### SUMMARY

The present disclosure provides a much needed device mounting system for mounting a device in an enclosure, where the mounting system can accommodate devices of different sizes without replacing any of the parts of the system.

Embodiments provide an axial mounting bracket that has an upper bracket that is fixed to a first end (for example, the top) of the device, and a plate attached to the upper bracket at an axis. The plate rotates about the axis. The plate has a slot, for example, a curved slot, that is offset from the axis. A pin that is fixed to the enclosure extends through the slot. As the plate is rotated about the axis, the pin controls the movement of the plate and the upper bracket by engaging and controlling the path of the slot. A distance between the slot and the axis and is different at different locations along the slot, causing the upper plate to move relative to the pin as the plate is rotated about the axis. A lower bracket attaches a second end (for example, a bottom end) of the device to the enclosure such that the second end of the device does not move (other than possibly pivoting) relative to the enclosure. Because, in this example, the lower bracket locationally fixes the second end of the device relative to the enclosure, the movement of the plate relative to the pin provide multiple positions of the upper bracket relative to the lower bracket. These multiple positions provide mounting for devices of different sizes using the same axial mounting bracket, thus eliminating the need to have different mounting brackets for different size devices.

While the above embodiment was described with reference to an upper bracket and a lower bracket, in other embodiments these brackets are mounted in different locations. For example, in some embodiments, the upper bracket is mounted to a bottom of the device and the lower bracket is mounted to a top of the device, or the upper bracket is mounted to one side of the device and the lower bracket is mounted to a different side of the device.

Embodiments provide a telecommunication component mounting system configured to allow mounting of different sized telecommunication components, including: a first mounting portion that may be structurally configured to attach a telecommunication component to an enclosure; and a second mounting portion that may be structurally configured to attach the telecommunication component to the enclosure. The first mounting portion may comprise an engaging portion that may be structurally configured to be fixed to the enclosure; the first mounting portion may comprise a moving portion that may be structurally configured to engage the engaging portion; wherein the moving portion is structurally configured to rotate about an axis; the first mounting portion may comprise a first connection portion that may be structurally configured to be fixed to the telecommunication component; the first connection portion may be structurally configured to couple with the moving portion such that the moving portion slidingly moves relative to the first connection portion; the engaging portion may comprise a pin; the moving portion may comprise a retaining portion that may be structurally configured to engage the engaging portion such that the engaging portion moves within the retaining portion; the retaining portion may be a curved slot; the second mounting portion may comprise an enclosure attachment portion that may be structurally configured to be fixed to the enclosure; the second mounting portion may comprise a component attachment portion that may be structurally configured to be fixed to the telecommunication component; the component attachment portion may be structurally configured to pivot relative to the enclosure attachment portion such that the telecommunication component may be configured to pivot relative to the enclosure; and the moving portion may be configured to rotate about the axis such that different sized telecommunication components are permitted to be mounted in the enclosure so as to avoid a need for different mounting parts for different sized telecommunication components, thereby resulting in a reduction of parts needed to mount different sized telecommunication components to the enclosure.

In embodiments, the first connection portion may comprise a component connection portion that is structurally configured to be fixed to the telecommunication component.

In embodiments, the first connection portion may comprise a moving portion connection portion that may be structurally configured to be rotatingly connected to the moving portion.

In embodiments, the component connection portion may be structurally configured to be fixed to the moving portion connection portion.

In embodiments, the axis may be structurally configured to be fixed relative to the moving portion connection portion.

In embodiments, the moving portion may be a plate.

In embodiments, the first connection portion may be a component mount, the component connection portion may be a component tab, and the moving portion connection portion may be a plate tab.

In embodiments, the telecommunication component mounting system may further comprise a biasing connection, and the biasing connection may be structurally configured to connect the moving portion to the first connection portion.

In embodiments, the biasing connection may comprise a spring.

In embodiments, the telecommunication component mounting system may further comprise a friction connection, and the friction connection may be structurally configured to connect the moving portion to the first connection portion.

In embodiments, the friction connection may comprise a wave washer.

Embodiments provide a telecommunication component mounting system configured to allow mounting of different sized telecommunication components, including: a first mounting portion that may be structurally configured to attach a telecommunication component to an enclosure; and a second mounting portion that may be structurally configured to attach the telecommunication component to the enclosure. The first mounting portion may comprise a moving portion that may be structurally configured to engage an engaging portion on the enclosure; the moving portion may be structurally configured to rotate about an axis; the moving portion may comprise a retaining portion that may be structurally configured to engage the engaging portion such that the engaging portion moves within the retaining portion; the retaining portion may be a curved slot; the second mounting portion may be structurally configured to be fixed to the enclosure and to the telecommunication component; the second mounting portion may be structurally configured to pivot relative to enclosure; and the moving portion may be configured to rotate about the axis such that different sized telecommunication components are permitted to be mounted in the enclosure so as to avoid a need for different mounting parts for different sized telecommunication components, thereby resulting in a reduction of parts needed to mount different size telecommunication components to the enclosure.

In embodiments, the first mounting portion may comprise the engaging portion that may be structurally configured to be fixed to the enclosure.

In embodiments, the first mounting portion may comprise a first connection portion that may be structurally configured to be fixed to the telecommunication component.

In embodiments, the first connection portion may be structurally configured to couple with the moving portion such that the moving portion slidingly moves relative to the first connection portion.

In embodiments, the engaging portion may comprise a pin.

In embodiments, the second mounting portion may comprise an enclosure attachment portion that may be structurally configured to be fixed to the enclosure, the second mounting portion may comprise a component attachment portion that may be structurally configured to be fixed to the telecommunication component, and the component attachment portion may be structurally configured to pivot relative to the enclosure attachment portion such that the telecommunication component is configured to pivot relative to the enclosure.

Embodiments provide a telecommunication component mounting system configured to allow mounting of different sized telecommunication components, including: a first mounting portion that may be structurally configured to attach a telecommunication component to an enclosure; and a second mounting portion that may be structurally configured to attach the telecommunication component to the enclosure. The first mounting portion may comprise a moving portion that may be structurally configured to engage the enclosure; the moving portion may comprise a retaining portion that may be structurally configured to engage an engaging portion of the enclosure such that the retaining portion slidingly moves relative to the engaging portion; the retaining portion may be a curved slot; and the moving portion may be configured to rotate about an axis such that different sized telecommunication components are permitted to be mounted in the enclosure so as to avoid a need for different mounting parts for different sized telecommunication components, thereby resulting in a reduction of parts needed to mount different sized telecommunication components to the enclosure.

In embodiments, the second mounting portion may be structurally configured to be fixed to the enclosure and to the telecommunication component.

In embodiments, the second mounting portion may be structurally configured to pivot relative to enclosure.

In embodiments, the first mounting portion may comprise the engaging portion that is structurally configured to be fixed to the enclosure.

In embodiments, the first mounting portion may comprise a first connection portion that may be structurally configured to be fixed to the telecommunication component.

In embodiments, the first connection portion may be structurally configured to couple with to the moving portion such that the moving portion slidingly moves relative to the first connection portion.

In embodiments, the engaging portion may comprise a pin.

In embodiments, the second mounting portion may comprise an enclosure attachment portion that may be structurally configured to be fixed to the enclosure, the second mounting portion may comprise a component attachment portion that may be structurally configured to be fixed to the telecommunication component, and the component attachment portion may be structurally configured to pivot relative to the enclosure attachment portion such that the telecommunication component is configured to pivot relative to the enclosure.

Various aspects of the system, as well as other embodiments, objects, features and advantages of this disclosure, will be apparent from the following detailed description of illustrative embodiments thereof, which is to be read in conjunction with the accompanying drawings.

### BRIEF DESCRIPTION OF THE DRAWINGS

FIG. 1 is a perspective view of an enclosure in accordance with various aspects of the disclosure.

FIG. 2 is a sectional view of the enclosure of FIG. 1.

FIG. 3 is a sectional view of the enclosure of FIG. 1.

FIG. 4 is a front sectional view of the enclosure of FIG. 1.

FIG. 5 is a front view of the enclosure of FIG. 1.

FIG. 6 is a perspective sectional view of the enclosure of FIG. 1.

FIG. 7 is a front view of the enclosure of FIG. 1.

FIG. 8 is a partial front view of the enclosure of FIG. 1 with a router of a first size mounted in the enclosure.

FIG. 9 is a partial front view of the enclosure of FIG. 1 with a router of a second size mounted in the enclosure.

FIG. 10 is a partial front view of the enclosure of FIG. 1 with a router of a third size mounted in the enclosure.

FIG. 11 is a partial front view of the enclosure of FIG. 1 with a router of a fourth size mounted in the enclosure.

FIG. 12 is a perspective view of a rotating bracket in accordance with various aspects of the disclosure, with the rotating bracket in a first position.

FIG. 13 is a perspective view of the rotating bracket of FIG. 12, with the rotating bracket in a second position.

FIG. 14 is a perspective view of the rotating bracket of FIG. 12, with the rotating bracket in a third position.

FIG. 15 is a perspective view of the rotating bracket of FIG. 12, with the rotating bracket in a fourth position.

FIG. 16 is a perspective view of an embodiment of the rotating bracket of FIG. 12 with a spring mechanism.

FIG. 17 is a perspective view of an embodiment of the rotating bracket of FIG. 12 with a wave washer mechanism.

FIG. 18 is a perspective view of a wave washer and nut used in the embodiment of FIG. 17.

### DETAILED DESCRIPTION OF EMBODIMENTS

Embodiments of the disclosure provide a telecommunications component mounting system that is structurally configured to mount telecommunications components of different sizes to an enclosure by rotating a plate about an axis and thus avoiding a need for different parts for different size devices, resulting in a reduction of parts needed for a technician to mount different size devices to the enclosure.

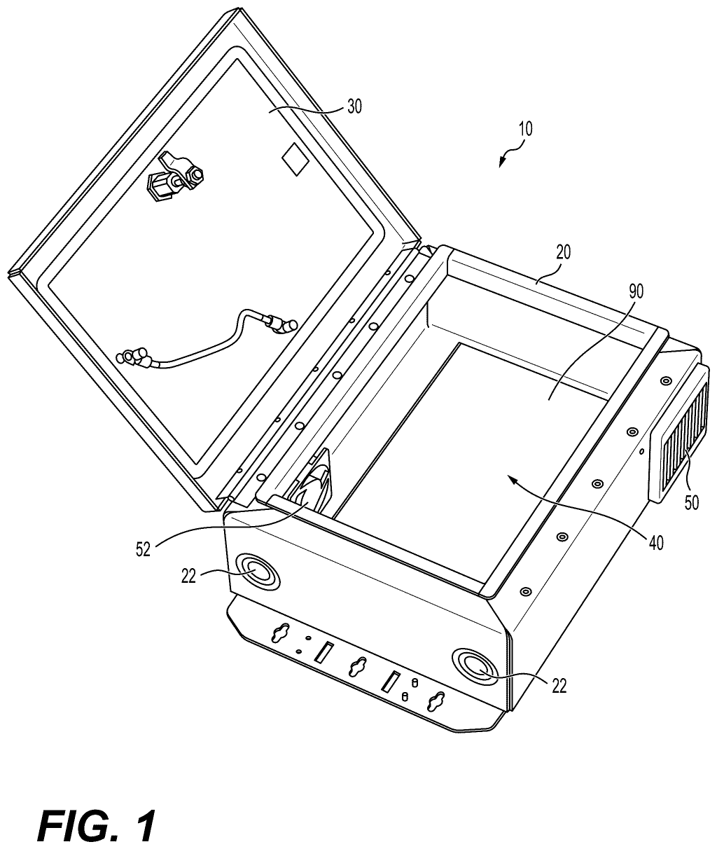

FIG. 1-4 show an example of an enclosure 10 that includes a cabinet 20 and a cover 30. The cabinet 20 has a plurality of cable entry ports 22 structurally configured to allow cables to pass from outside the cabinet 20 to an internal space 40 of the cabinet 20. A plurality of ventilation openings 50 are provided to allow ventilation air to enter and exit the cabinet 20 to provide cooling to a device, for example, a telecommunications component such as, for example, a device, router, or modem, 90 located in the interior space 40. Ventilation fans 52 are provided to move ventilation air through the ventilation openings 50. Also shown is a power supply 80 such as, for example, a 120 volt power strip for supplying power to the device 90. In embodiments, the device 90 is an ethernet modem.

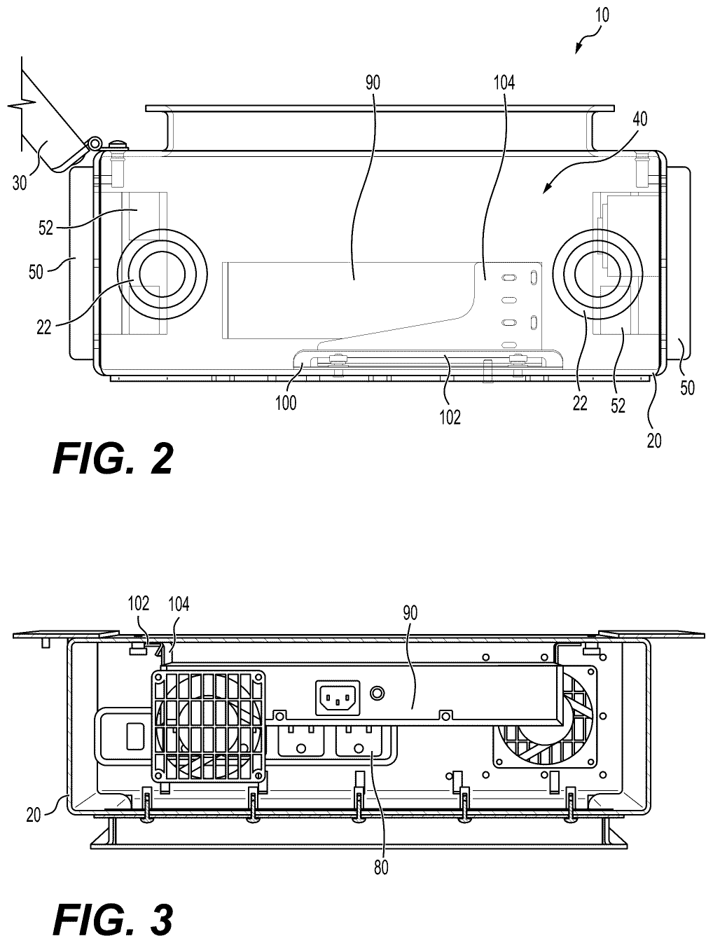

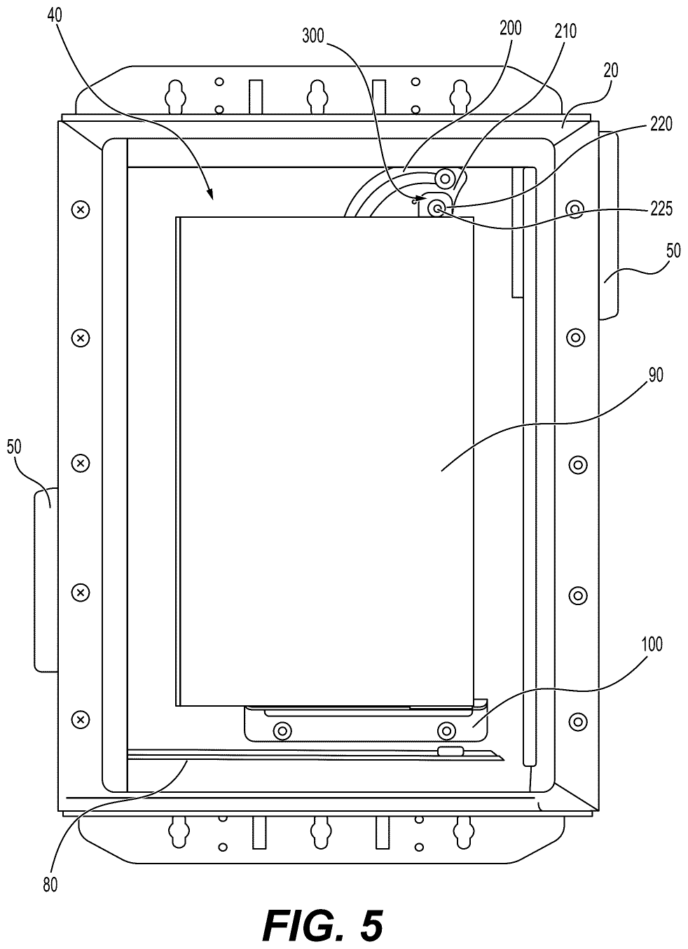

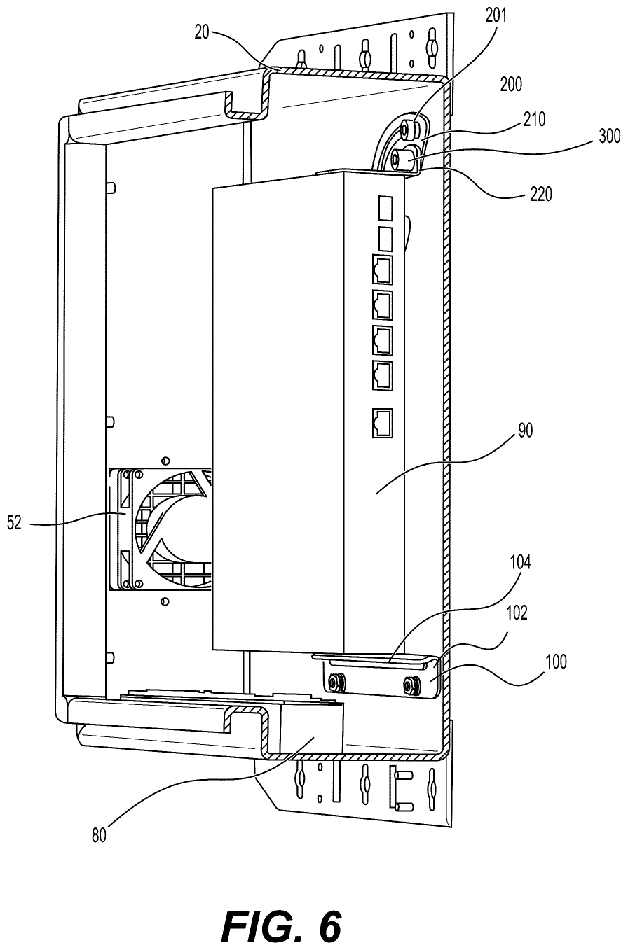

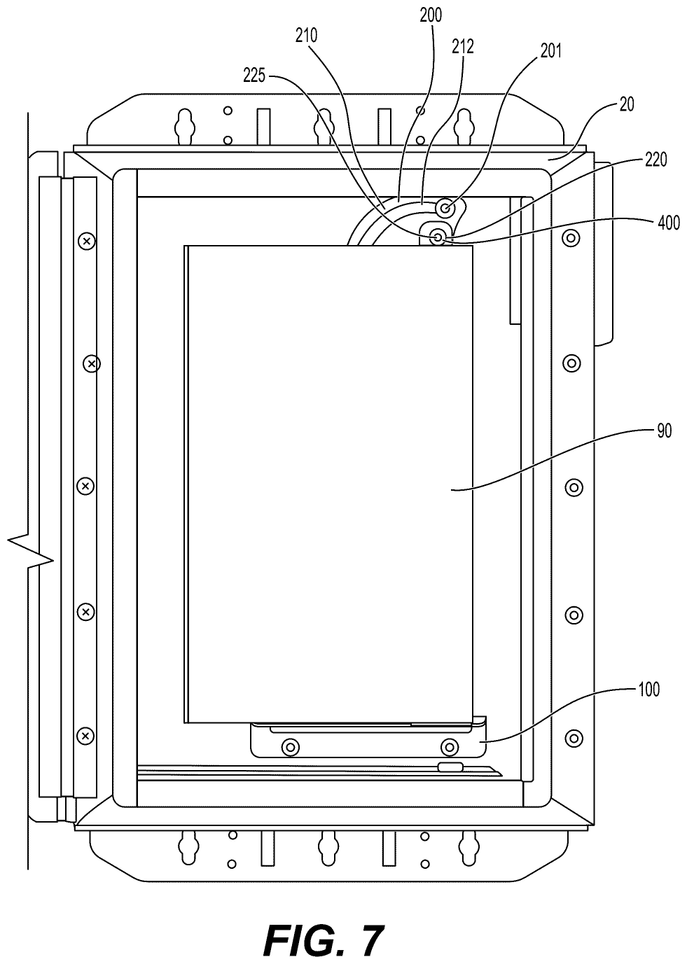

As shown in FIGS. 2-7, the device 90 is attached to the cabinet 20 by a first mounting portion, for example, a first mount (upper bracket), 200 and a second mounting portion, for example, a second mount (lower bracket), 100. In this example, the upper bracket 200 attaches the top of the device 90 to the cabinet 20, and the lower bracket 100 attaches the bottom of the device 90 to the cabinet 20. In other configurations, different sides of the device 90 are attached to the cabinet 20 by way of the upper bracket 200 and the lower bracket 100.

In the example shown in FIG. 2, the lower bracket 100 has an enclosure attachment portion, for example, a second mount enclosure attachment portion (lower bracket enclosure tab), 102 that is structurally configured to be fixed to the enclosure 20. In the example shown in FIG. 2, the lower bracket 100 has a component attachment portion, for example, a second mount device attachment portion (lower bracket device tab), 104 that is structurally configured to be fixed to the device 90. In this example, the lower bracket enclosure tab 102 is formed as one piece of plastic, metal, or other material, and the lower bracket device tab 104 is formed as a separate piece of plastic, metal, or other material. In embodiments, a portion of the lower bracket device tab 104 is inserted into a slot in the lower bracket enclosure tab 102 such that the top of the device 90 can pivot away from a back wall of the enclosure while the device 90 remains attached to the cabinet 20 by the lower bracket 100. In embodiments, the lower bracket 100 is formed as one piece of plastic, metal, or other material that includes the lower bracket enclosure tab 102 and the lower bracket device tab 104.

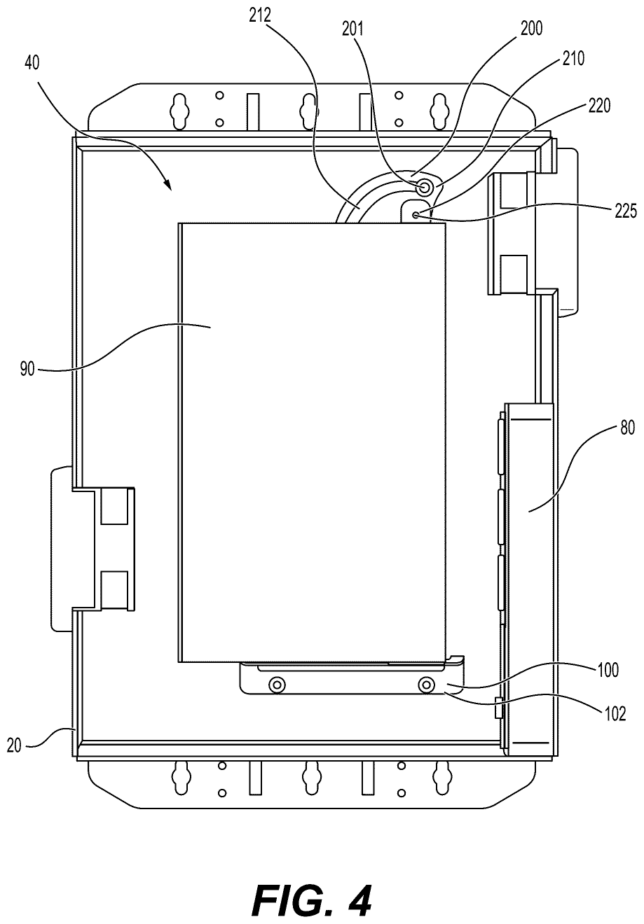

In the example shown in FIGS. 4-7, the top of the device 90 is attached to the cabinet 20 by the upper bracket 200. In this example, the device 90 has a height of 11.6 inches, a width of 7.1 inches, and a thickness of 1.7 inches. In other examples, the device 90 has has a height in the range of 9.5 inches to 11.8 inches. In other examples, the device 90 has a different height. An engaging portion, for example, a pin, 201 is fixed to a back wall of the cabinet 20 and does not move relative to the cabinet 20. The upper bracket 200 has a moving portion, for example, a rotating portion (plate), 210 that rotates about an axis 225. In embodiments, the axis 225 is a protrusion such as, for example, an axis pin that extends from either the plate 210 or a first connection portion, for example, a device mount, 220 that is fixed to the device 90. The plate 210 has a retaining portion, for example, a curved slot, 212 that is structurally configured to receive the pin 201. In the example shown in FIG. 4, the device mount 220 has a first connection portion, for example, a device connection portion (device tab), 221 and a moving portion connection portion (plate tab) 222. In the example shown in FIG. 4, the device tab 221 is structurally configured to be fixed to the device 90. In the example shown in FIG. 4, the plate tab 222 is structurally configured to be rotatably connected to the plate 210 at the axis 225.

In embodiments, the plate 210 is pre-attached to the device mount 220 at the axis 225. A technician attaches the device tab 221 to the device 90 (with, for example, machine screws) with the plate attached to the plate tab 222, and attaches the lower bracket device tab 104 to the device 90 (with, for example, machine screws). The technician then slides a portion of the lower bracket device tab 104 into the slot in the lower bracket enclosure tab 102 to positionally fix the lower end of the device 90 to the cabinet 20. The technician then pivots the device 90 such that the top end of the device 90 (with the plate 210 attached) approaches a back wall of the cabinet 20. During this pivoting, the plate 210 is rotated to the position where the pin 201 can be inserted into the slot 212 and attached to the back wall of the cabinet 20 (by, for example, a threaded connection). In some embodiments, the pin 201 is fixed to the back wall of the cabinet 20 prior to attaching the lower bracket device tab 104 to the lower bracket enclosure tab 102, and the pin 201 is sized to pass through the slot 212. In these embodiments, the pin 201 includes a cap that attaches to the pin 201 after the plate 210 is in place on the pin 201 and retains the plate 210 in position on the pin 201.

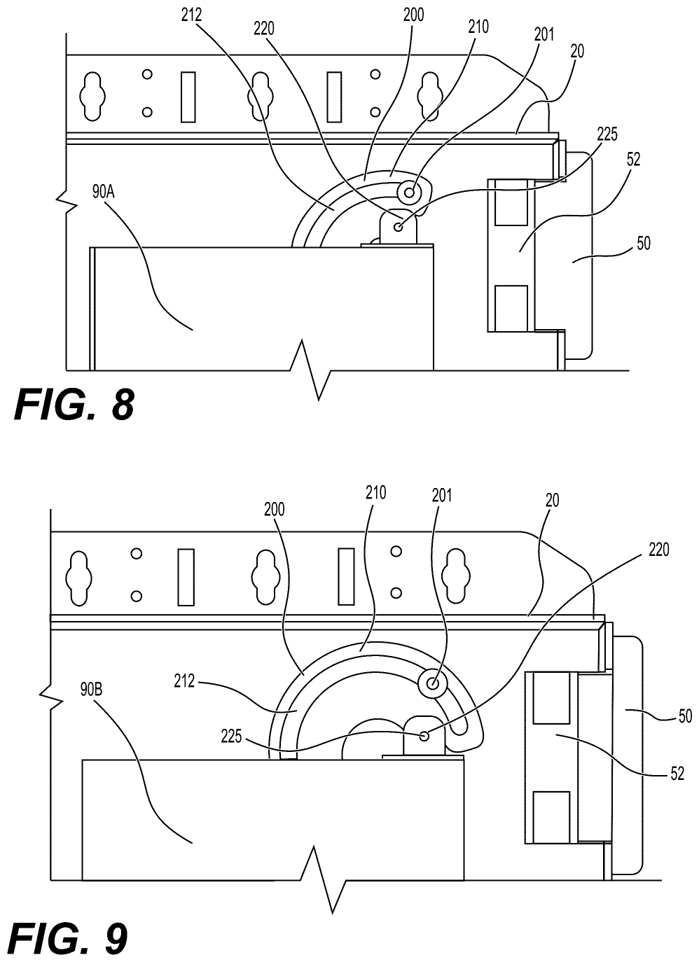

An advantage of the plate 210 being able to rotate is illustrated with reference to FIGS. 8-15. FIGS. 8-11 show four different positions of the plate 210. Each of these positions corresponds to one of four devices 90A, 90B, 90C, 90D, each having a different height. Because the location of the bottom of the devices 90A, 90B, 900, 90D is fixed due to the lower bracket 100 being fixed relative to the cabinet 20, any difference in height of the devices 90A, 90B, 90C, 90D is adapted to by the upper bracket 200.

FIG. 8 shows the device 90A having the largest height of the four examples. In FIG. 8, the plate 210 is in a position in which the pin 201 is located at one end of the slot 212. In this position, the axis 225 is in the closest possible position to the pin 201 such that the distance between the axis 225 and the pin 201 is the smallest of the four examples. This position accommodates the device 90A with the largest height.

FIG. 11 shows the device 90D having the smallest height of the four examples. In FIG. 11, the plate 210 is in a position in which the pin 201 is located at the end of the slot 212 opposite the end occupied by the pin 210 in FIG. 8. In this position, the axis 225 is in the farthest possible position from the pin 201 such that the distance between the axis 225 and the pin 201 is the largest of the four examples. This position accommodates the device 90D with the smallest height.

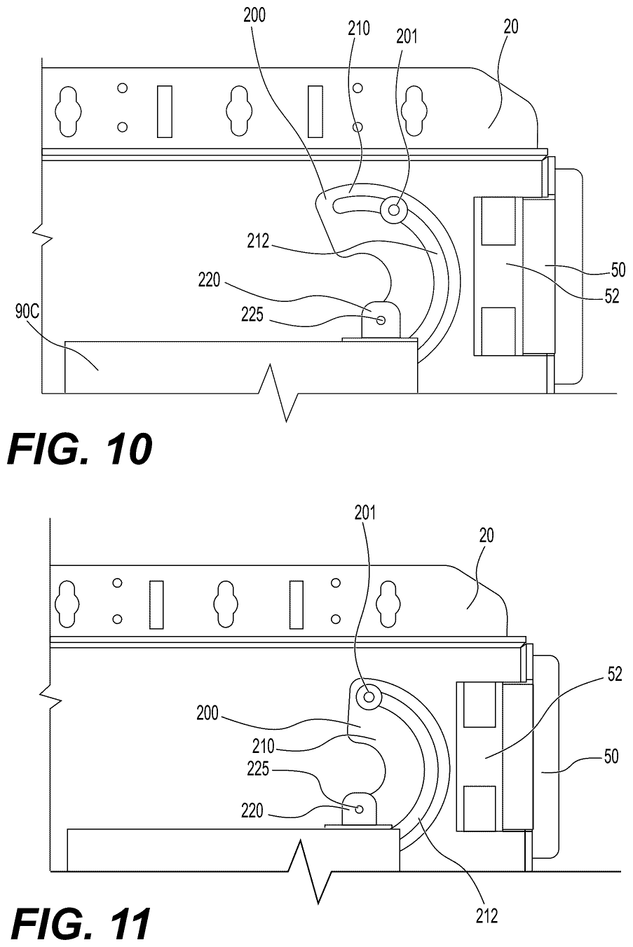

FIGS. 9 and 10 show the plate 210 in two of an infinite number of intermediate positions such that the pin 201 is in locations along the slot 212 that are between the two ends of the slot 212. These positions accommodate, for example, devices 90B, 90C having heights between that shown in FIG. 8 and that shown in FIG. 11.

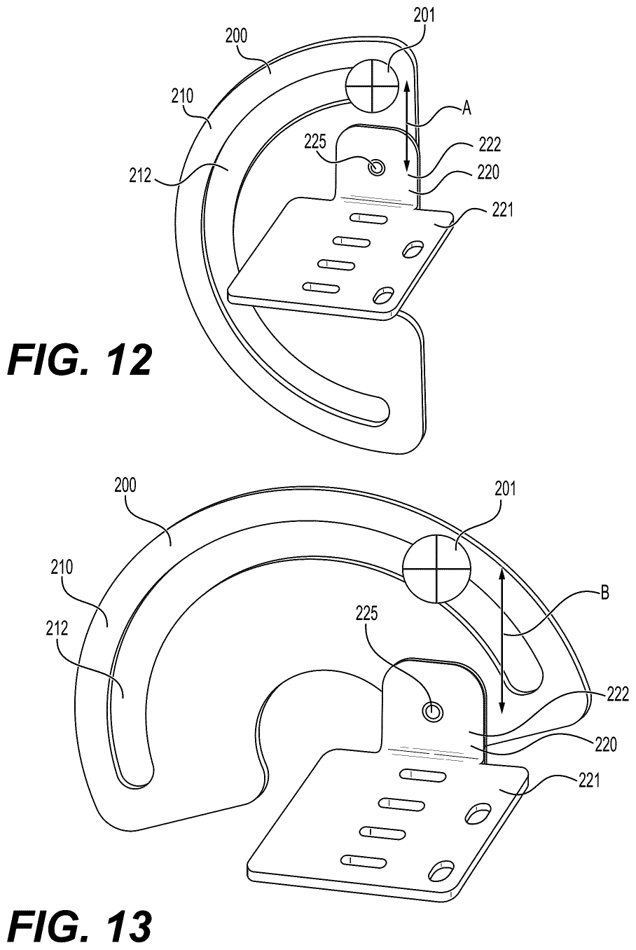

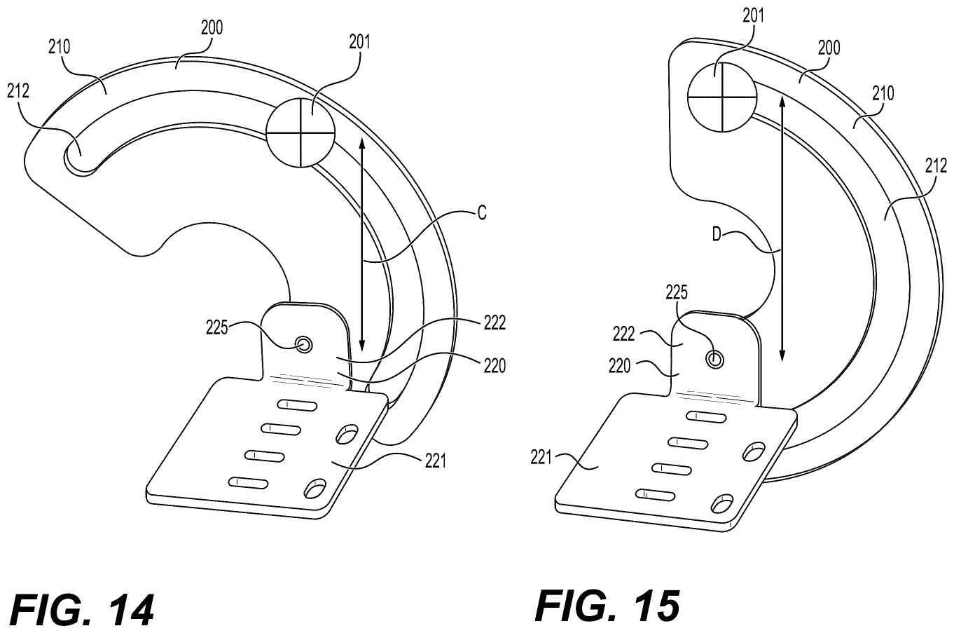

FIGS. 12-15 show in more detail the positions of the plate 210 shown in FIGS. 8-11, respectively. In FIG. 12, a short distance A (in this example, 0.75 inches or 19 mm) between the pin 201 and the axis 225 is achieved to accommodate the device 90A having the largest height. In FIG. 15, a long distance D (in this example, 2.187 inches or 55.5 mm) between the pin 201 and the axis 225 is achieved to accommodate the device 90D having the shortest height. FIGS. 13 and 14 show intermediate distances B and C. Note that in FIGS. 12-15, the pin 201 is in a fixed position relative to the back wall of the cabinet 20. The different distances A, B, C, D are achieved by rotation of the plate 210 and the resulting movement of the device tab 221 as required to correspond to the top of the different devices 90A, 90B, 90C, 90D. While particular dimensions are disclosed for the example shown, other embodiments have plates 210, slots 212, and plate tabs 222 of different dimension that provide different distances between the pin 201 and the axis 225 to accommodate devices 90 of different heights.

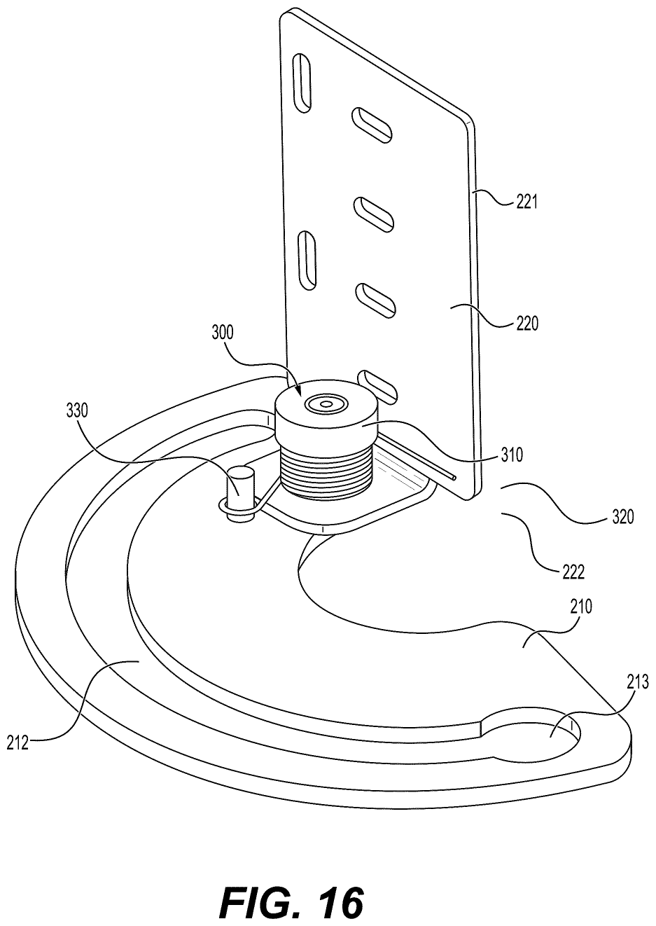

There are multiple ways to attach the plate 210 to the device mount 220. One example of an attachment mechanism is the biasing connection, for example, a spring mount, 300 shown in FIG. 16. In the example shown in FIG. 16, a connecting portion (nut) 310 is used to attach a biasing portion, for example, a spring, 320 to the plate tab 222 of the device mount 220. A biasing portion restraining portion (spring pin) 330 is fixed to the plate 210 and provides an anchor point for one end of the spring 320. The other end of the spring 320 is restrained by the device tab 221 of the device mount 220.

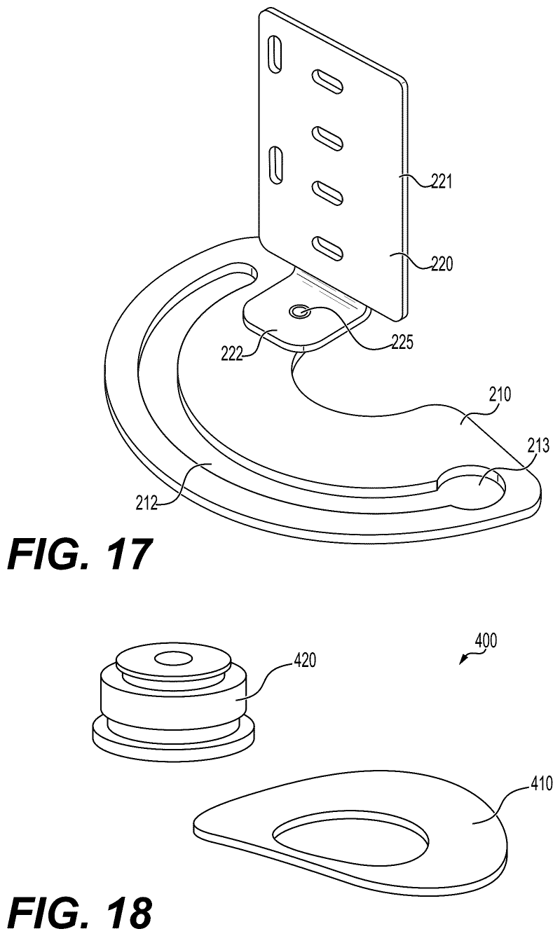

FIGS. 17 and 18 show another example of an attachment mechanism for attaching the plate 210 to the device mount 220. In this example, a friction connection, for example, a friction mount, 400 includes an axial biasing portion, for example, a wave washer, 410 held in place between the plate 210 and the plate tab 222 by a retaining portion (nut) 420. The wave washer 410 creates forces against the plate 210 and the plate tab 222 that increase the friction that must be overcome to move the plate 210 relative to the plate tab 222.

FIGS. 16 and 17 show an embodiment of the slot 212 having an enlarged area 213 at one end of the slot 212. The enlarged area 213 provides an opening through which the pin 201 (shown, for example, in FIGS. 12-15) can pass without having to remove the pin 201 from the back wall of the cabinet 20.

Note that in each of the FIGS. 8-11, the plate 210 remains attached to the device mount 220 at the axis 225. The only difference in the mounting system in the four cases shown in FIGS. 8-11 is the rotational position of the plate 210 (to adjust for the different heights of the various devices 90A, 90B, 90C, 90D). The upper bracket 200 provides the advantage of being able to accommodate devices 90A, 90B, 90C, 90D, for example, of different heights without having to change any parts. Other mounting systems have the disadvantage of requiring one or more parts of the mounting system to be replaced depending on the size (height) of the device being mounted in the enclosure.

Although the illustrative embodiments of the present invention have been described herein with reference to the accompanying drawings, it is to be understood that the invention is not limited to those precise embodiments, and that various other changes and modifications may be effected therein by one skilled in the art without departing from the scope or spirit of the invention.

Various changes to the foregoing described and shown structures will now be evident to those skilled in the art. Accordingly, the particularly disclosed scope of the invention is set forth in the following claims.

What is claimed is:

1. A telecommunication component mounting system configured to allow mounting of different sized telecommunication components, comprising:
a first mounting portion structurally configured to attach a telecommunication component to an enclosure;
a second mounting portion structurally configured to attach the telecommunication component to the enclosure;
wherein the first mounting portion comprises an engaging portion that is structurally configured to be fixed to the enclosure;
wherein the first mounting portion comprises a moving portion that is structurally configured to engage the engaging portion;
wherein the moving portion is structurally configured to rotate about an axis;
wherein the first mounting portion comprises a first connection portion that is structurally configured to be fixed to the telecommunication component;
wherein the first connection portion is structurally configured to couple with the moving portion such that the moving portion slidingly moves relative to the first connection portion;
wherein the engaging portion comprises a pin;
wherein the moving portion comprises a retaining portion that is structurally configured to engage the engaging portion such that the engaging portion moves within the retaining portion;
wherein the retaining portion is a curved slot;
wherein the second mounting portion comprises an enclosure attachment portion that is structurally configured to be fixed to the enclosure;
wherein the second mounting portion comprises a component attachment portion that is structurally configured to be fixed to the telecommunication component;
wherein the component attachment portion is structurally configured to pivot relative to the enclosure attachment portion such that the telecommunication component is configured to pivot relative to the enclosure; and
wherein the moving portion is configured to rotate about the axis such that different sized telecommunication components are permitted to be mounted in the enclosure so as to avoid a need for different mounting parts for different sized telecommunication components, thereby resulting in a reduction of parts needed to mount different sized telecommunication components to the enclosure.

2. The telecommunication component mounting system of claim 1, wherein the first connection portion comprises a component connection portion that is structurally configured to be fixed to the telecommunication component.

3. The telecommunication component mounting system of claim 2, wherein the first connection portion comprises a moving portion connection portion that is structurally configured to be rotatingly connected to the moving portion.

4. The telecommunication component mounting system of claim 3, wherein the component connection portion is structurally configured to be fixed to the moving portion connection portion.

5. The telecommunication component mounting system of claim 3, wherein the axis is structurally configured to be fixed relative to the moving portion connection portion.

6. The telecommunication component mounting system of claim 1, wherein the moving portion is a plate.

7. The telecommunication component mounting system of claim 1, wherein the first connection portion is a component mount, the component connection portion is a component tab, and the moving portion connection portion is a plate tab.

8. The telecommunication component mounting system of claim 1, further comprising a biasing connection;
wherein the biasing connection is structurally configured to connect the moving portion to the first connection portion.

9. The telecommunication component mounting system of claim 8, wherein the biasing connection comprises a spring.

10. The telecommunication component mounting system of claim 1, further comprising a friction connection;
wherein the friction connection is structurally configured to connect the moving portion to the first connection portion.

11. The telecommunication component mounting system of claim 1, wherein the friction connection comprises a wave washer.

12. A telecommunication component mounting system configured to allow mounting of different sized telecommunication components, comprising:
a first mounting portion structurally configured to attach a telecommunication component to an enclosure;
a second mounting portion structurally configured to attach the telecommunication component to the enclosure;
wherein the first mounting portion comprises a moving portion that is structurally configured to engage an engaging portion on the enclosure;
wherein the moving portion is structurally configured to rotate about an axis;
wherein the moving portion comprises a retaining portion that is structurally configured to engage the engaging portion such that the engaging portion moves within the retaining portion;
wherein the retaining portion is a curved slot;
wherein the second mounting portion is structurally configured to be fixed to the enclosure and to the telecommunication component;
wherein the second mounting portion is structurally configured to pivot relative to enclosure; and
wherein the moving portion is configured to rotate about the axis such that different sized telecommunication components are permitted to be mounted in the enclosure so as to avoid a need for different mounting parts for different sized telecommunication components, thereby resulting in a reduction of parts needed to mount different size telecommunication components to the enclosure.

13. The telecommunication component mounting system of claim 12, wherein the first mounting portion comprises the engaging portion that is structurally configured to be fixed to the enclosure.

14. The telecommunication component mounting system of claim 13, wherein the first mounting portion comprises a first connection portion that is structurally configured to be fixed to the telecommunication component.

15. The telecommunication component mounting system of claim 14, wherein the first connection portion is structurally configured to couple with the moving portion such that the moving portion slidingly moves relative to the first connection portion.

16. The telecommunication component mounting system of claim 12, wherein the engaging portion comprises a pin.

17. The telecommunication component mounting system of claim 12, wherein the second mounting portion comprises an enclosure attachment portion that is structurally configured to be fixed to the enclosure, the second mounting portion comprises a component attachment portion that is structurally configured to be fixed to the telecommunication component, and the component attachment portion is structurally configured to pivot relative to the enclosure attachment portion such that the telecommunication component is configured to pivot relative to the enclosure.

18. A telecommunication component mounting system configured to allow mounting of different sized telecommunication components, comprising:
a first mounting portion structurally configured to attach a telecommunication component to an enclosure;
a second mounting portion structurally configured to attach the telecommunication component to the enclosure;
wherein the first mounting portion comprises a moving portion that is structurally configured to engage the enclosure;
wherein the moving portion comprises a retaining portion that is structurally configured to engage an engaging portion of the enclosure such that the retaining portion slidingly moves relative to the engaging portion;
wherein the retaining portion is a curved slot; and
wherein the moving portion is configured to rotate about an axis such that different sized telecommunication components are permitted to be mounted in the enclosure so as to avoid a need for different mounting parts for different sized telecommunication components, thereby resulting in a reduction of parts needed to mount different sized telecommunication components to the enclosure.

19. The telecommunication component mounting system of claim 18, wherein the second mounting portion is structurally configured to be fixed to the enclosure and to the telecommunication component.

20. The telecommunication component mounting system of claim 18, wherein the second mounting portion is structurally configured to pivot relative to enclosure.

21. The telecommunication component mounting system of claim 18, wherein the first mounting portion comprises the engaging portion that is structurally configured to be fixed to the enclosure.

22. The telecommunication component mounting system of claim 18, wherein the first mounting portion comprises a first connection portion that is structurally configured to be fixed to the telecommunication component.

23. The telecommunication component mounting system of claim 22, wherein the first connection portion is structurally configured to couple with the moving portion such that the moving portion slidingly moves relative to the first connection portion.

24. The telecommunication component mounting system of claim 18, wherein the engaging portion comprises a pin.

25. The telecommunication component mounting system of claim 18, wherein the second mounting portion comprises an enclosure attachment portion that is structurally configured to be fixed to the enclosure, the second mounting portion comprises a component attachment portion that is structurally configured to be fixed to the telecommunication component, and the component attachment portion is structurally configured to pivot relative to the enclosure attachment portion such that the telecommunication component is configured to pivot relative to the enclosure.
